(19) United States
(12) Patent Application Publication
(10) Pub. No.: US 2024/0194507 A1
(43) Pub. Date: Jun. 13, 2024

(54) SUBSTRATE PROCESSING APPARATUS, MODEL DATA GENERATION APPARATUS, SUBSTRATE PROCESSING METHOD, AND MODEL DATA GENERATION METHOD

(71) Applicant: Tokyo Electron Limited, Tokyo (JP)

(72) Inventors: Tsuyoshi MORIYA, Tokyo (JP); Takayuki YAMAGISHI, Fuchu City, Tokyo (JP); Haruhiko FURUYA, Nirasaki City, Yamanashi (JP); Kiyoshi MORI, Fuchu City, Tokyo (JP)

(73) Assignee: Tokyo Electron Limited, Tokyo (JP)

(21) Appl. No.: 18/585,466

(22) Filed: Feb. 23, 2024

Related U.S. Application Data
(63) Continuation of application No. PCT/JP2022/030940, filed on Aug. 16, 2022.

(30) Foreign Application Priority Data
Aug. 24, 2021 (JP) 2021-136079

(51) Int. Cl. H01L 21/67; G06N 20/00; H01L 21/687

(52) U.S. Cl. CPC H01L 21/67253; G06N 20/00; H01L 21/67207; H01L 21/67259; H01L 21/68764

(57) ABSTRACT

The storage is configured to store model data generated based on data including, in patterns, a processing condition for substrate processing, an attitude of a movable part that affects a processing result of the substrate processing, and the processing result of the substrate processing. The processing controller is configured to use the model data stored in the storage to control the substrate processing, including control of the processing condition for the substrate processing and control of the attitude of the movable part, according to a condition to be satisfied by the processing result of the substrate processing.

### CROSS-REFERENCE TO RELATED APPLICATIONS

This application is a bypass continuation application of international application No. PCT/JP2022/030940 having an international filing date of Aug. 16, 2022 and designating the United States, the international application being based upon and claiming the benefit of priority from Japanese Patent Application No. 2021-136079, filed on Aug. 24, 2021, the entire contents of each are incorporated herein by reference.

### TECHNICAL FIELD

The present disclosure relates to a substrate processing apparatus, a model data generation apparatus, a substrate processing method, and a model data generation method.

### BACKGROUND

Patent Document 1 discloses that, in order to measure effects of several processing parameters on a cleaning rate and uniformity on the cleaning rate in dry cleaning processing of a plasma processing system, such processing parameters are changed by an experimental design method.

### CITATION LIST

### Patent Documents

Patent Document 1: JP2007-535169A

### SUMMARY

The present disclosure provides a substrate processing apparatus, a model data generation apparatus, a substrate processing method, and a model data generation method, which can appropriately control substrate processing according to a condition to be satisfied by a processing result of the substrate processing.

A substrate processing apparatus according to an aspect of the present disclosure includes a storage and a processing controller. The storage is configured to store model data generated based on data including, in patterns, a processing condition for substrate processing, an attitude of a movable part that affects a processing result of the substrate processing, and the processing result of the substrate processing. The processing controller is configured to use the model data stored in the storage to control the substrate processing, including control of the processing condition for the substrate processing and control of the attitude of the movable part, according to a condition to be satisfied by the processing result of the substrate processing.

According to the present disclosure, it is possible to appropriately control the substrate processing according to the condition to be satisfied by the processing result of the substrate processing.

### BRIEF DESCRIPTION OF DRAWINGS

FIG. 1 is a view illustrating an example of a configuration of a substrate processing system according to one embodiment.

FIG. 2 is a schematic cross-sectional view illustrating an example of a configuration of a substrate processing apparatus according to one embodiment.

FIG. 3 is an enlarged cross-sectional view illustrating an example of a structure of an absorption mechanism according to one embodiment.

FIG. 4 is a diagram illustrating an example of a functional configuration of a model data generation apparatus according to one embodiment.

FIG. 5 is a flowchart illustrating an example of a flow of a model data generation method according to one embodiment.

FIG. 6 is a diagram schematically illustrating an example of a data configuration of training data according to one embodiment.

FIG. 7 is a flowchart illustrating an example of a flow of a substrate processing method according to one embodiment.

### DETAILED DESCRIPTION

Hereinafter, an embodiment of a substrate processing apparatus, a model data generation apparatus, a substrate processing method, and a model data generation method disclosed in the present application will be described in detail with reference to the drawings. The substrate processing apparatus, the model data generation apparatus, the substrate processing method, and the model data generation method disclosed herein are not limited by the following embodiment.

The substrate processing apparatus needs to appropriately control substrate processing according to a condition to be satisfied by a processing result of the substrate processing. However, the substrate processing apparatus has many parameters that can be changed with respect to the substrate processing. Therefore, it may take too much time for the substrate processing apparatus to change the respective parameters to perform the substrate processing, measure the processing result of the substrate processing, and determine appropriate settings for the respective parameters. Therefore, in the related art, the processing result is measured while changing the parameters for only a part of the parameters. However, in the related art, a combination of values of the respective parameters corresponding to the condition to be satisfied by the processing result of the substrate processing cannot be identified, and thus the substrate processing may not be appropriately controlled.

Therefore, the present disclosure provides a technique for appropriately controlling substrate processing according to a condition to be satisfied by a processing result of the substrate processing.

### Embodiment

### [Schematic Configuration of Substrate Processing System 300]

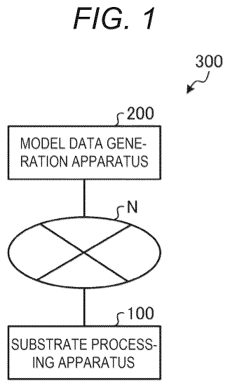

Embodiments will be described. First, an example of a substrate processing system including a substrate processing apparatus and a model data generation apparatus according to the present disclosure will be described. FIG. 1 is a view illustrating an example of a configuration of the substrate processing system 300 according to one embodiment.

The substrate processing system 300 includes a substrate processing apparatus 100 and a model data generation apparatus 200. The substrate processing apparatus 100 and the model data generation apparatus 200 are connected to a network N and can communicate with each other via the network N. As an aspect of the network N, mobile communication such as a cellular phone, Internet, and any type of communication network such as a local area network (LAN) or a virtual private network (VPN) can be adopted, regardless of a wired or wireless manner.

The model data generation apparatus 200 is, for example, a computer such as a server computer. The model data generation apparatus 200 generates model data to be used by the substrate processing apparatus 100 to control substrate processing. In the embodiment, a case in which the model data generation apparatus 200 is one computer is described as an example, and the model data generation apparatus 200 may be implemented as a computer system using a plurality of computers.

The substrate processing apparatus 100 is an apparatus that performs the substrate processing on a substrate. The substrate processing apparatus 100 acquires the model data from the model data generation apparatus 200, and uses acquired model data to control the substrate processing. Hereinafter, a case in which the substrate processing apparatus 100 is used as a film forming apparatus, and the substrate processing apparatus 100 performs film formation processing as the substrate processing will be mainly described as an example.

### [Configuration of Substrate Processing Apparatus 100]

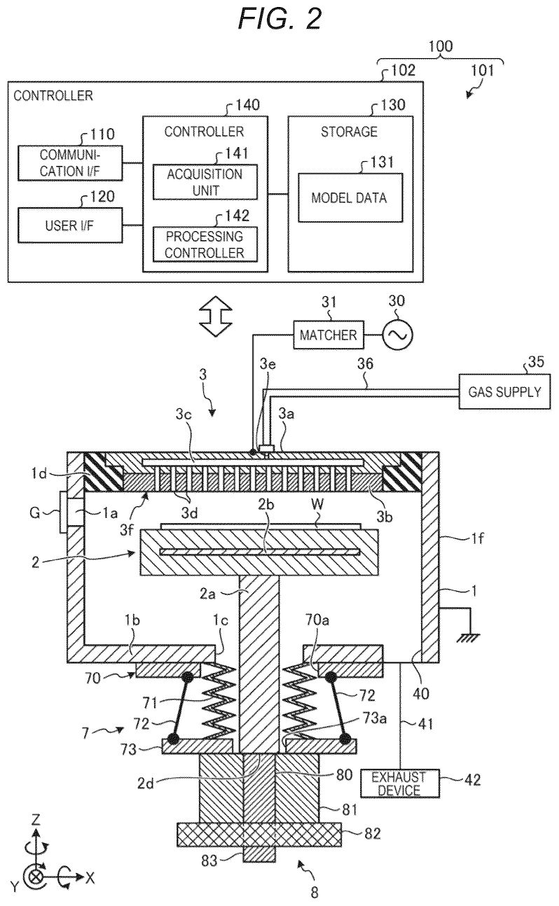

Next, the configuration of each apparatus will be described. First, an example of the configuration of the substrate processing apparatus 100 will be described. FIG. 2 is a schematic cross-sectional view illustrating an example of a configuration of the substrate processing apparatus 100 according to one embodiment. The substrate processing apparatus 100 illustrated in FIG. 2 is an apparatus that performs film formation in a vacuum atmosphere. For example, the substrate processing apparatus 100 illustrated in FIG. 2 is an apparatus that performs chemical vapor deposition (CVD) processing using a plasma on a substrate W. The substrate processing apparatus 100 includes a main body 101 that performs the substrate processing, and a controller 102 that controls the main body 101.

The main body 101 includes a processing container 1 formed into a substantially cylindrical shape made of metal such as aluminum or nickel and having an anodized coating film formed on a surface thereof. The processing container 1 has a bottom wall 1b and a side wall 1f. The processing container 1 is grounded. The processing container 1 is implemented to be airtight so that an inner space thereof can be maintained in the vacuum atmosphere. An opening 1a for loading and unloading the substrate W is formed in the side wall 1f of the processing container 1. The opening 1a is opened and closed by a gate valve G.

A stage 2 is provided inside the processing container 1. The stage 2 is formed into a flat, substantially columnar shape and made of, for example, metal such as aluminum or nickel, or aluminum nitride (AlN) in which a metal mesh electrode is embedded. The substrate W to be processed, such as a semiconductor wafer, is placed on an upper surface of the stage 2. The stage 2 also functions as a lower electrode. The stage 2 is supported from below by a support member 2a. An opening 1c is formed in the bottom wall 1b of the processing container 1 below the stage 2. The support member 2a is formed into a substantially cylindrical shape. The support member 2a extends vertically downward from the stage 2 and penetrates the opening 1c of the bottom wall 1b of the processing container 1. The opening 1c has a diameter larger than a diameter of the support member 2a.

The stage 2 has a built-in heater 2b. The heater 2b generates heat according to power supplied from outside of the processing container 1, and heats the substrate W placed on the stage 2. Although not illustrated, a flow path to which a coolant whose temperature is controlled by a chiller unit provided outside the processing container 1 is supplied is formed inside the stage 2. The stage 2 can control the substrate W to a predetermined temperature by heating by the heater 2b and cooling by the coolant supplied from the chiller unit. The stage 2 may not be provided with the heater 2b, and the temperature control of the substrate W may be performed by the coolant supplied from the chiller unit.

Although not illustrated, an electrode that generates an electrostatic force by a voltage supplied from the outside is embedded in the stage 2. The substrate W is attracted and held on the upper surface of the stage 2 by the electrostatic force generated from the electrode. Although not illustrated, the stage 2 includes lifting and lowering pins for transferring the substrate W to and from a transport mechanism (not illustrated) provided outside the processing container 1.

A shower head 3 is provided above the stage 2 and is formed into a substantially disk shape and made of a conductive metal such as aluminum or nickel. A space between a lower surface of the shower head 3 and the upper surface of the stage 2 is a processing space where the film formation processing is performed. The shower head 3 is supported on an upper portion of the stage 2 through an insulating member 1d made of ceramic or the like. Accordingly, the processing container 1 and the shower head 3 are electrically insulated from each other. The shower head 3 serves as a ceiling portion of the processing container 1. The shower head 3 is an example of an upper portion wall.

The shower head 3 has a top plate 3a and a shower plate 3b. The top plate 3a is provided to close the inside of the processing container 1 from the upper side. The shower plate 3b is provided below the top plate 3a to face the stage 2. The top plate 3a has a gas diffusion chamber 3c. A plurality of gas discharge holes 3d communicating with the gas diffusion chamber 3c are formed in the top plate 3a and the shower plate 3b.

A gas introduction port 3e for introducing a gas into the gas diffusion chamber 3c is formed in the top plate 3a. A gas supply 35 is connected to the gas introduction port 3e through a pipe 36. The gas supply 35 has a gas supply source for various gases used for the film formation processing, and a gas supply line connected to each gas supply source. Each gas supply line is provided with a control device for controlling a flow of the gas, such as a valve and a flow rate controller. The gas supply 35 supplies various gases whose flow rates are controlled by the control device provided in each gas supply line to the shower head 3 through the pipe 36. The gas supplied to the shower head 3 diffuses through the gas diffusion chamber 3c and is discharged from the respective gas discharge holes 3d into the processing space below the shower head 3.

The shower plate 3b pairs with the stage 2 and also functions as an electrode plate for forming a capacitively coupled plasma (CCP) in the processing space. A radio frequency (RF) power supply 30 is connected to the shower head 3 through a matcher 31. The RF power supply 30 supplies RF power to the shower head 3 through the matcher 31. The RF power supplied from the RF power source 30 to the shower head 3 is supplied from the lower surface of the shower head 3 into the processing space. The gas supplied into the processing space is formed into a plasma by the RF power supplied into the processing space. The RF power supply 30 may supply the RF power to the stage 2 instead of the shower head 3. In this case, the shower head 3 is grounded. In addition, the RF power source 30 may supply the RF power of different frequencies and magnitudes to both the stage 2 and the shower head 3.

A lower end 2d of the support member 2a that supports the stage 2 is positioned outside the processing container 1 and connected to a rotor 8. The rotor 8 includes a rotation shaft 80, a vacuum seal 81, and a motor 82. The lower end 2d of the support member 2a is connected to an upper end of the rotation shaft 80. The rotation shaft 80 rotates around an axis passing through a center of the stage 2, integrally with the support member 2a. A slip ring 83 is provided at a lower end of the rotation shaft 80. The slip ring 83 has electrodes and is electrically connected to various wirings for supplying power to components inside the stage 2. For example, the slip ring 83 is electrically connected to a wiring for supplying power to the heater 2b embedded in the stage 2. For example, the slip ring 83 is electrically connected to a wiring that applies a voltage to the electrode for attracting the substrate W onto the stage 2 by the electrostatic force.

The motor 82 rotates the rotation shaft 80. By rotation of the rotation shaft 80, the stage 2 rotates through the support member 2a. When the rotation shaft 80 rotates, the slip ring 83 rotates together with the rotation shaft 80. However, the electric connection between the slip ring 83 and the wiring is maintained.

The vacuum seal 81 is, for example, a magnetic fluid seal and is provided around the rotation shaft 80. The vacuum seal 81 can maintain the smooth rotation of the rotation shaft 80 while hermetically sealing the rotation shaft 80.

The substrate processing apparatus 100 includes a movable part inside the processing container 1. The substrate processing apparatus 100 according to the embodiment includes the stage 2 as the movable part. The stage 2 can change an attitude. The substrate processing apparatus 100 changes the attitude of the stage 2 on which the substrate W is placed, thereby affecting the processing result of the substrate processing.

The substrate processing apparatus 100 includes a driving mechanism that changes the attitude of the movable part. The substrate processing apparatus 100 according to the embodiment includes a driving mechanism 7 capable of changing the attitude of the stage 2. The driving mechanism 7 is connected to the lower end 2d of the support member 2a through the vacuum seal 81. The driving mechanism 7 includes an absorption mechanism 70, a bellows 71, a plurality of (for example, six) actuators 72, and a base member 73.

The bellows 71 is provided to surround a periphery of the support member 2a. An upper end of the bellows 71 penetrates an opening 70a formed in the absorption mechanism 70 and is connected to the bottom wall 1b of the processing container 1. A lower end of the bellows 71 is connected to the base member 73. Accordingly, the bellows 71 hermetically seals a space between the bottom wall 1b of the processing container 1 and the base member 73. The bellows 71 is extensible and contractible according to a movement of the base member 73.

The base member 73 is connected to the lower end 2d of the support member 2a positioned outside the processing container 1 through the vacuum seal 81. The base member 73 can move integrally with the support member 2a and the stage 2. The base member 73 has an opening 73a having a diameter larger than a diameter of the lower end 2d of the support member 2a. The support member 2a penetrates the opening 73a, and the lower end 2d of the support member 2a is connected to the rotation shaft 80. The vacuum seal 81 is provided around the rotation shaft 80 connected to the lower end 2d of the support member 2a. The base member 73 is fixed to an upper surface of the vacuum seal 81. Accordingly, the base member 73 is connected to the stage 2 through the vacuum seal 81, the rotation shaft 80, and the support member 2a, and can be moved integrally with the stage 2.

The plurality of actuators 72 are provided in parallel with each other between the bottom wall 1b of the processing container 1 and the base member 73. The plurality of actuators 72 can change an inclination of the stage 2 by relatively changing an inclination of the base member 73 with respect to the bottom wall 1b of the processing container 1. In addition, the plurality of actuators 72 can change a position of the stage 2 by relatively changing a position of the base member 73 with respect to the bottom wall 1b of the processing container 1. The plurality of actuators 72 are extensible and contractible, and are connected to the base member 73 in a rotationally slidable manner through a universal joint, and are connected to the bottom wall 1b side of the processing container 1 in a rotationally slidable manner through a universal joint.

The plurality of actuators 72 and the base member 73 form a parallel linkage that can move the base member 73 in, for example, an X-axis direction, a Y-axis direction, and a Z-axis direction illustrated in FIG. 2, and in directions of rotation around the X-axis, around the Y-axis, and around the Z-axis, respectively. A movement coordinate system of the parallel linkage formed by the plurality of actuators 72 and the base member 73 is adjusted in advance to coincide with a coordinate system of the processing container 1. When the bottom wall 1b of the processing container 1 and the base member 73 are connected to each other by the parallel linkage, the plurality of actuators 72 can relatively move the base member 73 with respect to the bottom wall 1b of the processing container 1. Accordingly, the attitude of the stage 2 can be adjusted. For example, the plurality of actuators 72 can change the inclination of the stage 2 by inclining the base member 73 in a predetermined direction (for example, in at least one of the directions of rotation around the X-axis, around the Y-axis, and around the Z-axis in FIG. 2) with respect to the bottom wall 1b of the processing container 1. In order to avoid a damage to the bellows 71, the rotation around the Z-axis may be limited. In addition, the plurality of actuators 72 can change the position of the stage 2 by moving the base member 73 in the predetermined direction (for example, in at least one of the X-axis direction, the Y-axis direction, and the Z-axis direction in FIG. 2) with respect to the bottom wall 1b of the processing container 1. The plurality of actuators 72 can lift and lower the stage 2 between a processing position and a transfer position by lifting and lowering the support member 2a.

The absorption mechanism 70 has the opening 70a communicating with the inside of the processing container 1 through the opening 1c of the bottom wall 1b of the processing container 1. The plurality of actuators 72 are connected to the absorption mechanism 70 without being connected to the bottom wall 1b of the processing container 1. Accordingly, even when the bottom wall 1b of the processing container 1 is deformed, a stress caused by the deformation of the bottom wall 1b of the processing container 1 is absorbed by the absorption mechanism 70. Therefore, the stress caused by the deformation of the bottom wall 1b of the processing container 1 is not transmitted to the plurality of actuators 72, so that a decrease in adjustment accuracy of the inclination of the stage 2 can be prevented.

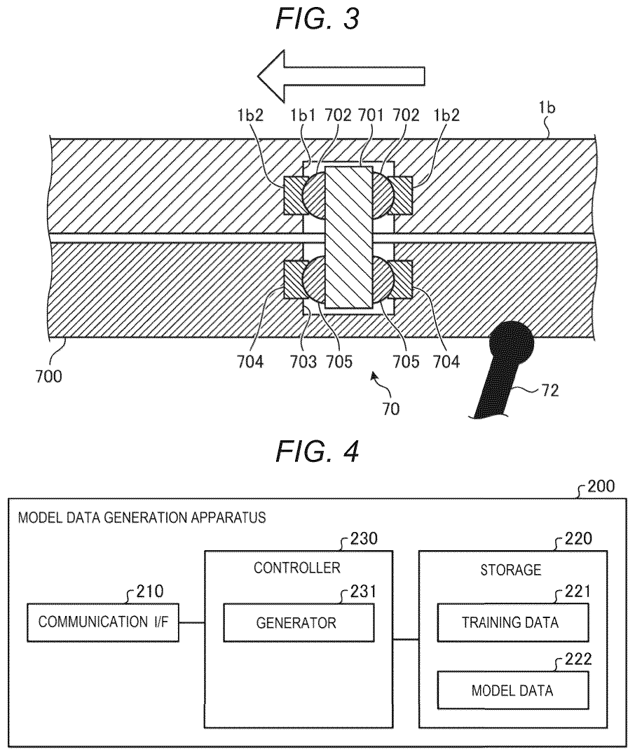

The absorption mechanism 70 is provided in the bottom wall 1b of the processing container 1 and absorbs the deformation of the bottom wall 1b of the processing container 1. FIG. 3 is an enlarged cross-sectional view illustrating an example of a structure of the absorption mechanism 70 according to one embodiment. The absorption mechanism 70 includes a plate member 700 and a link member 701.

The plate member 700 is formed in a plate shape and in an annular shape, and is disposed below the bottom wall 1b of the processing container 1. The plate member 700 is disposed apart from the bottom wall 1b of the processing container 1 from the viewpoint of blocking the transmission of heat and vibration from the processing container 1.

One end of the link member 701 is connected to the bottom wall 1b of the processing container 1 in a rotationally slidable manner, and the other end of the link member 701 is connected to the plate member 700 in a rotationally slidable manner. For example, as shown in FIG. 3, a recess 1b1 is formed in the bottom wall 1b of the processing container 1, and a spherical bearing 1b2 is provided in the recess 1b1. A spherical convex portion 702 is formed at one end of the link member 701. By connecting the convex portion 702 to the spherical bearing 1b2, the link member 701 is connected to the bottom wall 1b of the processing container 1 in a rotationally slidable manner through the convex portion 702 and the spherical bearing 1b2. Meanwhile, a recess 703 is formed in an upper surface of the plate member 700 at a position corresponding to the recess 1b1 of the processing container 1. A spherical bearing 704 is provided in the recess 703. A spherical convex portion 705 is formed at the other end of the link member 701. By connecting the convex portion 705 to the spherical bearing 704, the link member 701 is connected to the plate member 700 in a rotationally slidable manner through the convex portion 705 and the spherical bearing 704.

The link member 701 rotates in a direction corresponding to the deformation of the bottom wall 1b of the processing container 1 to prevent the transmission of the deformation to the plate member 700. For example, when the bottom wall 1b of the processing container 1 is deformed in a direction indicated by an arrow in FIG. 3, the link member 701 receives the stress of the deformation of the bottom wall 1b. However, by rotating together with the bottom wall 1b in the direction indicated by the arrow in FIG. 3, the transmission of the stress to the plate member 700 due to the deformation of the bottom wall 1b is prevented. The plurality of actuators 72 are connected to the plate member 700. Accordingly, the stress caused by the deformation of the bottom wall 1b of the processing container 1 is not transmitted to the plurality of actuators 72 through the plate member 700, so that a decrease in adjustment accuracy of the position and the inclination of the stage 2 can be prevented.

A plurality of link members 701 are disposed along an extending direction of the plate member 700. In the embodiment, for example, three link members 701 are provided at substantially equal intervals along the extending direction of the plate member 700. Four or more link members 701 may be provided at substantially equal intervals along the extending direction of the plate member 700.

Reference will again be made to FIG. 2. An exhaust port 40 is formed in the bottom wall 1b of the processing container 1. An exhaust device 42 is connected to the exhaust port 40 through a pipe 41. The exhaust device 42 includes a vacuum pump, a pressure adjusting valve, and the like. The exhaust device 42 can reduce a pressure inside the processing container 1 to a predetermined vacuum level.

The controller 102 is, for example, a computer and controls each part of the main body 101. An operation of the substrate processing apparatus 100 is collectively controlled by the controller 102. The controller 102 includes a communication I/F (interface) 110, a user I/F 120, a storage 130, and a controller 140.

The communication I/F 110 can communicate with other apparatuses to input and output various types of data. For example, the communication I/F 110 is connected to the network N, and transmits and receives various types of information to and from the model data generation apparatus 200 via the network N. For example, the communication I/F 110 receives the model data from the model data generation apparatus 200.

The user I/F 120 includes a keyboard through which a process administrator inputs commands for managing the substrate processing apparatus 100, and a display for visualizing and displaying an operating status of the substrate processing apparatus 100.

The storage 130 stores control programs (software) and various programs for implementing various types of processing performed by the substrate processing apparatus 100 under control of the controller 140. In addition, the storage 130 stores various types of data used in the program executed by the controller 140. For example, the storage 130 stores recipes in which processing condition data and the like are stored, and model data 131. The program or data may be used by being stored in a computer-readable computer recording medium (for example, a hard disk, an optical disk such as a DVD, a flexible disk, and a semiconductor memory). It is also possible to transmit the program or the data from another apparatus as necessary through, for example, a dedicated line and use the program or data on-line.

The controller 140 includes a central processing unit (CPU) and a memory, and controls each part of the substrate processing apparatus 100. The controller 140 reads a control program stored in the storage 130 and executes processing of the read control program. The controller 140 functions as various processors when the various control programs operates. For example, the controller 140 has functions of an acquisition unit 141 and a processing controller 142. In the embodiment, a case in which the controller 140 has the functions of the acquisition unit 141 and the processing controller 142 will be described as an example. However, the functions of the acquisition unit 141 and the processing controller 142 may be implemented in a distributed manner by a plurality of controllers. For example, the acquisition unit 141 and the processing controller 142 may be implemented by being distributed by different controllers capable of performing data communication with each other.

The acquisition unit 141 acquires the model data. In the embodiment, the model data is generated in the model data generation apparatus 200. The acquisition unit 141 acquires model data 222 to be described later from the model data generation apparatus 200 via the network N. The acquisition unit 141 stores the acquired model data 222 in the storage 130 as the model data 131.

The processing controller 142 uses the model data 131 to control the substrate processing, including control of the processing condition for the substrate processing and control of the attitude of the movable part, according to a condition to be satisfied by the processing result of the substrate processing. In the embodiment, the processing controller 142 uses the model data 131 to determine a processing condition for the film formation processing and the attitude of the stage 2, according to a condition to be satisfied by the processing result of the film formation processing. Further, the processing controller 142 controls the film formation processing to be performed under the determined processing condition for the substrate processing and in the determined attitude of the stage 2. Details of the control performed by the processing controller 142 will be described later.

### [Configuration of Model Data Generation Apparatus 200]

Next, a configuration of the model data generation apparatus 200 will be described. FIG. 4 is a diagram illustrating an example of a functional configuration of the model data generation apparatus 200 according to one embodiment. The model data generation apparatus 200 includes a communication I/F 210, a storage 220, and a controller 230. The model data generation apparatus 200 may include other devices owned by the computer, in addition to the devices described above.

The communication I/F 210 can communicate with other apparatuses to input and output various types of data. For example, the communication I/F 210 is connected to the network N, and transmits and receives various types of information to and from the substrate processing apparatus 100 via the network N. For example, the communication I/F 210 receives data including the processing result of the substrate processing.

The storage 220 is a storage apparatus such as a hard disk, an SSD, or an optical disc. The storage 220 may be a semiconductor memory capable of rewriting data such as a RAM, a flash memory, or an NVSRAM.

The storage 220 stores an operating system (OS) or various programs to be executed by the controller 230. The storage 220 stores various types of data used in the program executed by the controller 230. For example, the storage 220 stores training data 221 and the model data 222. The storage 220 may store other data in addition to the data illustrated above.

Here, the substrate processing apparatus 100 needs to appropriately control the substrate processing according to the condition to be satisfied by the processing result of the substrate processing. However, the substrate processing apparatus 100 has many parameters that can be changed with respect to the substrate processing. Therefore, it may take too much time for the substrate processing apparatus 100 to change the respective parameters to perform the substrate processing, measure the processing result of the substrate processing, and determine appropriate settings for the respective parameters.

Therefore, in the embodiment, the model data 222 for controlling the substrate processing is generated using the training data 221, and the substrate processing is controlled using the model data 222.

The training data 221 is data used to generate the model data 222. The training data 221 includes various types of data to be used for the generation of the model data 222. For example, the training data 221 includes, in patterns, the processing condition for the substrate processing, the attitude of the movable part that affects the processing result of the substrate processing, and the processing result of the substrate processing. In the embodiment, the training data 221 includes, in patterns, the processing condition for the film formation processing, the attitude of the stage 2 during the film formation processing, and the processing result of the film formation processing.

The data including the processing result of the substrate processing stored in the training data 221 may be data including a processing result obtained by actually performing the substrate processing, or may be the data including a simulation result obtained by simulating the substrate processing. The training data 221 in the embodiment includes data including the processing result obtained by actually performing the substrate processing and data including the simulation result obtained by simulating the substrate processing.

The model data 222 is data that stores a control model generated using machine learning.

The controller 230 is a device that controls the model data generation apparatus 200. As the controller 230, an electronic circuit such as a CPU or an MPU, or an integrated circuit such as an ASIC or an FPGA can be adopted. The controller 230 has an internal memory for storing programs defining various process procedures or control data, and executes various processes by the programs and the control data. The controller 230 functions as various processors by the various programs operating. For example, the controller 230 includes a generator 231.

The generator 231 is a processor that generates the model data. The generator 231 uses the training data 221 to perform the machine learning, and generates the model data for deriving the processing condition for the substrate processing and the attitude of the movable part, according to the condition to be satisfied by the processing result of the substrate processing. The generator 231 stores the generated model data in the storage 220 as the model data 222.

### [Model Data Generation Method]

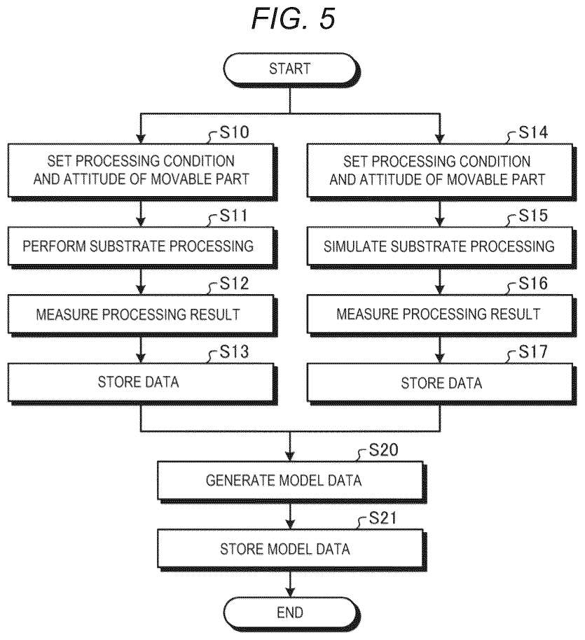

FIG. 5 is a flowchart illustrating an example of a flow of a model data generation method according to one embodiment. When the model data is generated, the training data 221 is prepared. The training data 221 is generated by actual substrate processing and simulation of the substrate processing.

Steps S10 to S13 in FIG. 5 illustrate a flow of generating the training data 221 by the actual substrate processing. The processing condition for the substrate processing and the attitude of the movable part that affects the processing result of the substrate processing are set in the substrate processing apparatus (step S10). Then, the substrate processing is performed by the substrate processing apparatus (step S11). Further, the processing result of the substrate processing is measured (step S12). Further, the processing condition for the performed substrate processing, the attitude of the movable part during the substrate processing, and the measured processing result of the substrate processing are stored in the training data 221 (step S13). In the generation of the training data 221 by the actual substrate processing, the processing condition for the substrate processing and the attitude of the movable part that affects the processing result of the substrate processing are changed in patterns, and the substrate processing is performed for each of the patterns, and the processing results of the substrate processing are measured. Then, for each pattern, the processing condition for the substrate processing, the attitude of the movable part during the substrate processing, and the measured processing result of the substrate processing are stored in the training data 221.

The substrate processing apparatus for performing the substrate processing for the training data 221 may be the actual substrate processing apparatus 100, or may be another substrate processing apparatus having the function same as that of the substrate processing apparatus 100. For example, when the substrate processing apparatus 100 is operating in a manufacturing process of a semiconductor device, the substrate processing may be performed to generate the training data 221 at predetermined timings other than in operation, such as when the substrate processing apparatus 100 is introduced or during maintenance. In addition, the substrate processing for the training data 221 may be performed by a substrate processing apparatus for development purposes different from the substrate processing apparatus 100. In the embodiment, the processing condition for the film formation processing and the attitude of the stage 2 during the film formation processing are set in the substrate processing apparatus 100. Further, the substrate processing apparatus 100 performs the film formation processing on the substrate W. Then, a film formed on the substrate W is measured.

In the embodiment, the training data 221 stores, for each pattern, the processing condition for the film formation processing, the attitude of the stage 2 during the film formation processing, and the processing result of the film formation processing.

The processing condition for the film formation processing may be any of processing parameters related to the film formation processing. As the processing parameters related to the film formation processing, for example, a gas type of a gas to be used for the film formation, a gas flow rate for each gas type, a supply time of the gas for each gas type, a pressure in the processing container 1, RF power, a processing temperature (for example, a temperature of the substrate W or a temperature of the heater 2b), a position of the substrate W on the stage 2, a process log (for example, the cumulative number of processing pieces from introduction or maintenance, a cumulative processing time from introduction or maintenance), a cross-sectional shape of the substrate W, a CD shape, a process parameter (a plasma potential, a matcher position, APC accuracy, and an HV current), plasma characteristics, gas analysis (for example, Q-Mass), an impedance of the processing container 1, an RF resonance, and a plasma density are listed. The processing parameters related to the film formation processing described above are examples, and are not limited thereto. For example, when a surface of the stage 2 on which the substrate W is placed is divided into annular regions, the heater 2b for each region is embedded, and the temperature of the heater 2b for each region can be controlled, the temperature of the heater 2b for each region or the temperature of the substrate W may be used as the processing parameters. When the shower head 3 is divided into a plurality of regions, and the RF power can be individually supplied to each region, the RF power, the RF frequency, and a power ratio between frequencies for each region may be used as the processing parameters. In addition, when the shower head 3 is divided into a plurality of regions, and the gas can be individually supplied from each region, a gas flow rate, a gas ratio, and a gas distribution for each region may be used as the processing parameters.

The attitude of the movable part may be any of control parameters for controlling the attitude, such as a position or a rotation angle of the movable part. In the embodiment, the control parameters for controlling the attitude of the stage 2 during the film formation processing include the positions of stage 2 in the X-axis direction, the Y-axis direction, and the Z-axis direction, and the rotation angles of the stage 2 around the X-axis, the Y-axis, and the Z-axis. The control parameters for controlling the attitude described above are examples, and are not limited thereto. For example, as the control parameter for controlling the attitude, a gap between the stage 2 and the shower head 3 or a rotation speed of the stage 2 may be used as the control parameter.

The processing result of the film formation processing may be any value indicating the processing result of the film formation. Examples of the value indicating the processing result of the film formation processing include a film thickness, uniformity, a coverage, a stress, a refractive index (RI), a film density, impurity, leak, a composition ratio, and roughness. The values indicating the processing result of the film formation processing described above are examples, and are not limited thereto. The processing result of the substrate processing such as the processing result of the film formation processing may be determined as a distribution. In the substrate processing apparatus 100, the substrate W to be processed is transferred and disposed at the same position on the stage 2. Therefore, for example, as the distribution of the processing results, measurement points may be determined in advance on the stage 2 or the substrate W, and values indicating the processing results at the respective measurement points may be determined. The measurement points are arranged at least at a central portion or a peripheral portion of the stage 2 or the substrate W. The measurement points are preferably uniformly arranged on the stage 2 or the substrate W. For example, the measurement points are arranged in a lattice shape or a concentric circle shape on the stage 2 or the substrate W. The measurement points may be arranged at a higher density on the stage 2 or on the substrate W in a region where the processing result is precisely controlled. For example, when precisely controlling the processing result near an edge of the substrate W, the measurement points may be arranged so that the density is higher in the area near the edge than near the center of the substrate W. In the embodiment, 300 measurement points are determined on the substrate W, and values indicating the processing results at the respective measurement points are measured.

Here, the substrate processing apparatus has many parameters that can be changed with respect to the substrate processing. For example, the substrate processing apparatus 100 according to the embodiment has many parameters that can be changed, such as the processing parameters related to the above-described film formation processing and the control parameters for controlling the attitude of the stage 2. Therefore, it may take too much time when the substrate processing apparatus 100 performs the substrate processing with various patterns while changing the respective parameters, and measures the processing result of the substrate processing to obtain the training data 221.

Therefore, in the model data generation method in the embodiment, the training data 221 is generated by simulation of the substrate processing together with the actual substrate processing.

Steps S14 to S17 in FIG. 5 illustrate a flow of generating the training data 221 by the simulation of the substrate processing. The processing condition for the substrate processing and the attitude of the movable part that affects the processing result of the substrate processing are set in a program for simulating the substrate processing (step S14). Then, the substrate processing is simulated based on the set processing condition for the substrate processing and the attitude of the movable part (step S15). Further, the processing result of the substrate processing is measured based on a simulation result (step S16). Further, the processing condition for the simulated substrate processing, the attitude of the movable part in the simulated substrate processing, and the measured processing result of the substrate processing are stored in the training data 221 (step S17). In the generation of the training data 221 by the simulation, the processing condition for the substrate processing and the attitude of the movable part that affects the processing result of the substrate processing are changed patterns, and the substrate processing is simulated for each of the patterns, and the processing results of the substrate processing are measured. Then, for each pattern, the processing condition for the substrate processing, the attitude of the movable part during the substrate processing, and the measured processing result of the substrate processing are stored in the training data 221. In the simulation, the processing result of the substrate processing can be determined under various processing conditions for the film formation processing and the attitudes of the movable part without performing the actual substrate processing. In the generation of the training data 221 by the simulation, the substrate processing is simulated with respect to various patterns other than the patterns performed in the actual substrate processing, and the processing result of the substrate processing is measured based on the simulation result. The patterns for simulating the substrate processing may include a pattern same as the pattern in the actual substrate processing.

In the embodiment, a state in which the film formation processing is performed under the processing condition for the film formation processing in the substrate processing apparatus 100 will be simulated. For example, a state inside the processing container 1 such as a plasma, a gas potential, and a density inside the processing container 1 during the film formation processing is determined by the simulation. Further, a state of a film formed on the substrate W on the stage 2 is determined by the simulation, according to the state inside the processing container 1 and the attitude of the stage 2. In the simulation, the state of the film formed on the substrate W can be determined under various processing conditions for the film formation processing and the attitudes of the stage 2 without performing the actual substrate processing.

In the embodiment, the training data 221 stores, for each pattern, the processing condition for the film formation processing, the attitude of the stage 2 during the film formation processing, and the processing result of the film formation processing.

In this way, the model data generation method in the embodiment can prepare the training data 221 in various patterns by performing the simulation of the substrate processing together with the actual substrate processing. In addition, as compared with a case in which only the actual substrate processing is performed, a time required for preparing the training data 221 can be shortened.

The training data 221 stores, for each pattern in which values of at least a part of the plurality of parameters, including the processing parameters of the substrate processing and the control parameters for controlling the attitude of the movable part, are changed, the values of the respective parameters of the pattern and the processing result of the substrate processing of the pattern. In the embodiment, the training data 221 stores, for each pattern in which the values of at least a part of the plurality of parameters, including the processing parameters of the film formation processing and the control parameters for controlling the attitude of the stage 2, are changed, the values of the respective parameters of the pattern and the processing result of the film formation processing performed on the pattern.

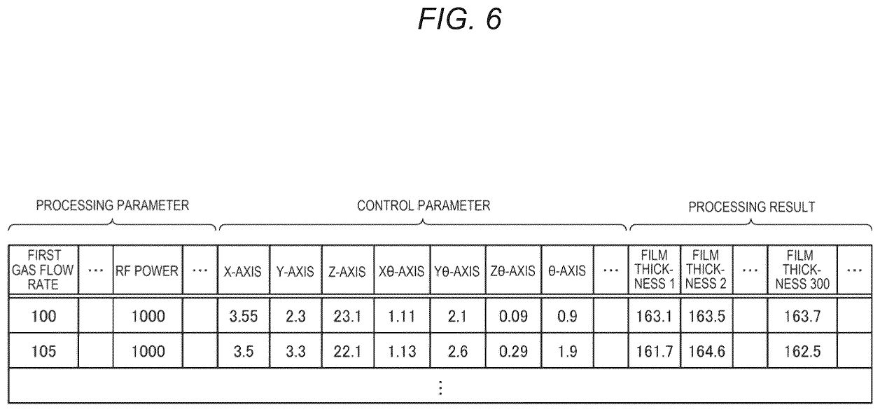

FIG. 6 is a diagram schematically illustrating an example of a data configuration of the training data 221 according to one embodiment. FIG. 6 illustrates a case in which the training data 221 has a data configuration in a table format. The training data 221 includes items for storing the processing parameters of the film formation processing, the control parameters for controlling the attitude of the stage 2, and the processing result of the film formation processing. For example, FIG. 6 illustrates a first gas flow rate and the RF power as examples of the processing parameters of the film formation processing. The first gas flow rate indicates a flow rate of a gas of a first gas type used for the film formation. The RF power indicates the RF power during the film formation processing. In FIG. 6, the X-axis, the Y-axis, the Z-axis, an Xθ-axis, a Yθ-axis, a Zθ-axis, and a θ-axis are illustrated as examples of the control parameters for controlling the attitude of the stage 2. The X-axis indicates the position of the stage 2 in the X-axis direction. The Y-axis indicates the position of the stage 2 in the Y-axis direction. The Z-axis indicates the position of the stage 2 in the Z-axis direction. The Xθ-axis indicates the rotation angle of the stage 2 around the X-axis. The Yθ-axis indicates the rotation angle of the stage 2 around the Y-axis. The Zθ-axis indicates the rotation angle of the stage 2 around the Z-axis. The θ-axis indicates the rotation angle at which the stage 2 is rotated by the rotation shaft 80. In addition, FIG. 6 illustrates a film thickness 1, a film thickness 2, . . . and a film thickness 300, as examples of the processing result of the film formation processing. The film thickness 1 indicates a film thickness at a predetermined first measurement point on the substrate W. The film thickness 2 indicates a film thickness at a predetermined second measurement point on the substrate W. The film thickness 300 indicates a film thickness at a predetermined 300-th measurement point on the substrate W. The training data 221 stores, for each pattern, the values of the respective items such as the processing parameters, the control parameters, and the processing results in one record.

Reference will again be made to FIG. 5. The generator 231 uses the training data 221 to perform the machine learning, and generates model data for deriving the processing condition for the substrate processing and the attitude of the movable part, according to the condition to be satisfied by the processing result of the substrate processing (step S20). The method of the machine learning may be any method as long as the model data for deriving the processing condition for the substrate processing and the attitude of the movable part can be generated according to the condition to be satisfied by the processing result of the substrate processing. Examples of the method of the machine learning that can be used for the generation of such model data include linear regression, an autoregressive moving average model (ARMA), a state space model, a k-nearest neighbor algorithm, a support vector machine, a decision tree, a random forest, a gradient boosting, and a neural network. For example, the generator 231 performs linear regression analysis on each pattern stored in the training data 221 to generate the model data. In the machine learning, a physical model of the substrate processing such as a relationship between parameters in the actual substrate processing may be set as a constraint. For example, in the film formation processing, when the film formation is performed under the same conditions except for the temperature of the heater 2b, the higher the temperature of the heater 2b, the higher the film formation rate. Therefore, for example, the constraint may be set that the film formation rate does not decrease when the temperature of the heater 2b increases.

In the embodiment, the generator 231 uses the training data 221 to perform the machine learning, and generates the model data for deriving the processing condition for the film formation processing and the attitude of the stage 2, according to the condition to be satisfied by the processing result of the film formation processing.

The generator 231 stores the generated model data in the storage 220 as the model data 222 (step S21).

The training data 221 may be updated as appropriate. The model data generation apparatus 200 may perform the machine learning using the updated training data 221 to update the training data 221. For example, the training data 221 is updated by periodically acquiring the processing condition for the actual substrate processing, the attitude of the movable part, and the processing result of the substrate processing from the substrate processing apparatus 100 operating in a manufacturing process of a semiconductor device. The generator 231 may perform the machine learning using the updated training data 221 to update the training data 221 according to the state of the substrate processing apparatus 100 during operation.

In addition, in the model data generation method, standard model data may be generated, the machine learning (reinforcement learning) may be performed according to each substrate processing apparatus, and model data suitable for each substrate processing apparatus may be generated based on the standard model data. For example, the training data 221 stores data related to a standard substrate processing apparatus. The generator 231 performs the machine learning using the training data 221 and generates the standard model data. Data including the processing condition for the actual substrate processing, the attitude of the movable part, and the processing result of substrate processing are acquired from the substrate processing apparatus 100 during operation. The generator 231 may perform the reinforcement learning using the acquired data, and generate, based on the standard model data, model data suitable for the substrate processing apparatus 100 during operation.

In the machine learning, it is possible to determine a contribution ratio that indicates a correlation with a processing result for each parameter, and to exclude a parameter with a low contribution ratio. In the machine learning, by excluding the parameter with the low contribution ratio, it is possible to narrow down the parameters to be used for the model data to the parameters that have the correlation. When the parameters that have the correlation are determined, the machine learning may be performed using the data including the parameters that have the correlation among the respective parameters stored in the training data 221. In addition, the training data 221 may be prepared for the parameters that have the correlation.

The substrate processing apparatus needs to appropriately set the processing condition for the substrate processing such that the processing result of the substrate processing becomes a desired result. In addition, when the attitude of the movable part affects the processing result of the substrate processing, it is also necessary to appropriately set the attitude of the movable part during the substrate processing. For example, in the substrate processing apparatus 100 according to the embodiment, since the attitude of the stage 2 affects a film to be formed on the substrate W or a distribution of the film, it is necessary to appropriately set the attitude of the stage 2 during the film formation processing.

However, in the substrate processing apparatus, there are many parameters that can be changed with respect to the substrate processing, such as the processing condition for the substrate processing and the attitude of the movable part, and it is difficult for a process administrator or the like to appropriately set each parameter so that the processing result of the substrate processing becomes the desired result.

Therefore, the substrate processing apparatus uses the model data to set the parameters that can be changed with respect to the substrate processing. For example, the substrate processing apparatus 100 according to the embodiment uses the model data to set the processing condition for the film formation processing, the attitude of the stage 2, and other parameters that can be changed with respect to the film formation processing.

The acquisition unit 141 of the substrate processing apparatus 100 acquires the model data 222 from the model data generation apparatus 200 via the network N. The model data generation apparatus 200 may transmit the model data 222 according to a request from the acquisition unit 141. In addition, the model data generation apparatus 200 may transmit the model data 222 at a predetermined timing, such as a timing at which the model data 222 is generated or updated. The acquisition unit 141 stores the acquired model data 222 in the storage 130 as the model data 131.

The processing controller 142 uses the model data 131 to control the substrate processing, including control of the processing condition for the substrate processing and control of the attitude of the movable part, according to a condition to be satisfied by the processing result of the substrate processing. For example, the processing controller 142 uses the model data 131 to control the substrate processing by the following substrate processing method.

### [Substrate Processing Method]

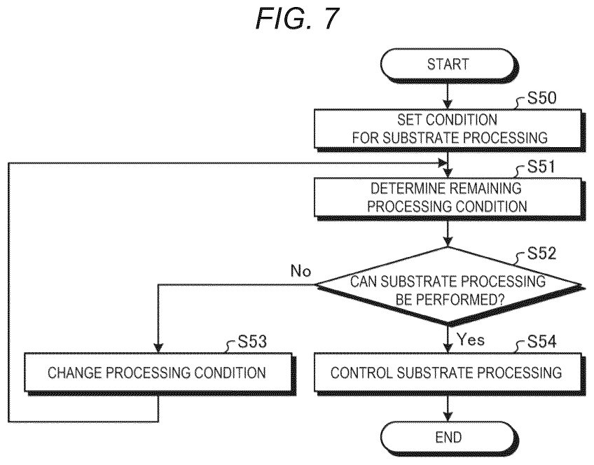

FIG. 7 is a flowchart illustrating an example of a flow of a substrate processing method according to one embodiment.

The controller 140 sets conditions for the substrate processing (step S50). For example, a part of the processing conditions for the substrate processing are set in the controller 140. For example, in the film formation processing, when a part of the film formation conditions, such as a gas type of a gas to be used and a gas flow rate for each gas type, are determined by a recipe or the like, the values of a part of the determined parameters are set. The controller 140 sets the condition to be satisfied by the processing result of the substrate processing. For example, in the film formation processing, a range to be satisfied by the formed film is set for each parameter indicative of a film formation result, such as a film thickness of a film to be formed on the substrate W. For example, when it is desired to form a film having a uniform film thickness on the substrate W, the range of the film thickness is set to be the same at each measurement point. Meanwhile, for example, when non-uniformity occurs on the substrate W as a result of processing in a process before the film formation processing and it is desired to form a film by the film formation processing so as to reduce the non-uniformity on the substrate W, the range of the film thickness at each measurement point is set so as to reduce the non-uniformity. For example, the range of the film thickness at each measurement point is set so that the film is thicker at the measurement point where the film on the substrate W is thin, and that the film is thinner at the measurement point where the film on the substrate W is thick.

The processing controller 142 uses the model data 131 to determine a remaining processing condition based on the condition to be satisfied by the processing result of the substrate processing and a part of the processing conditions for the substrate processing (step S51). For example, the processing controller 142 uses the model data 131 to determine values of remaining parameters based on the condition to be satisfied and the values of a part of the parameters among the plurality of parameters. For example, the processing controller 142 performs calculation by setting, in the model data 131, the set range of the parameters indicative of the film formation result at each measurement point, and the set values of a part of the parameters indicative of the film formation condition. The model data 131 outputs, as a calculation result, values of remaining parameters indicative of the film formation condition. When the remaining parameters include the control parameters for controlling the attitude of the movable part, the model data 131 outputs values of the control parameters. For example, the model data 131 outputs, as the control parameters for controlling the attitude of the stage 2, the positions of stage 2 in the X-axis direction, the Y-axis direction, and the Z-axis direction, and the rotation angles of the stage 2 around the X-axis, the Y-axis, and the Z-axis. In addition, the model data 131 outputs, as the calculation result, the processing result of the substrate processing at each measurement point. For example, the model data 131 outputs the film thickness at each measurement point. The model data 131 outputs reliability of the calculation result. When the processing condition for the substrate processing is not particularly set, the processing controller 142 may use the model data 131 to determine all values of the parameters indicative of the processing condition for the substrate processing based on the condition to be satisfied.

Based on the result determined based on the model data 131, the processing controller 142 determines whether the substrate processing can be performed (step S52). For example, the processing controller 142 determines whether the processing result of the substrate processing determined using the model data 131 satisfies the condition to be satisfied by the processing result of the substrate processing. For example, the processing controller 142 determines, for each parameter indicative of the film formation result, whether the film formation result output from the model data 131 is within the range to be satisfied by the formed film. For example, the processing controller 142 determines whether the film thickness at each measurement point output from the model data 131 is within the set range of the film thickness. In addition, the processing controller 142 determines whether the reliability of the calculation result is equal to or higher than a predetermined threshold value.

When the processing result of the substrate processing determined using the model data 131 satisfies the condition to be satisfied by the processing result of the substrate processing and the reliability of the calculation result is equal to or higher than the predetermined threshold value, the processing controller 142 determines that the substrate processing can be performed. For example, when the film formation result output from the model data 131 is within the range to be satisfied and the reliability of the calculation result is equal to or higher than the predetermined threshold value, the processing controller 142 determines that substrate processing can be performed. On the other hand, when the film formation result output from the model data 131 is not within the range to be satisfied by the formed film, or when the reliability of the calculation result is less than the predetermined threshold value, the processing controller 142 determines that the substrate processing cannot be performed.

When it is determined that the substrate processing cannot be performed (step S52: No), the processing controller 142 changes the condition to be satisfied by the processing result of the substrate processing and a part of the set processing conditions for the substrate processing (step S53), and proceeds to step S51 to determine the remaining processing condition again. In this case, for example, the processing controller 142 may loose at least a part of the conditions to be satisfied by the processing result of the substrate processing, such as expanding the range to be satisfied by the formed film. When it is determined that the substrate processing cannot be performed, the processing condition for the substrate processing determined as not able to be performed and the processing result of the substrate processing may be additionally learned by the model data 131.

On the other hand, when it is determined that the substrate processing can be performed (step S52: Yes), the processing controller 142 uses the set values of a part of the parameters and the determined values of the remaining parameters to control the substrate processing, including control of the processing condition for the substrate processing and control of the attitude of the movable part (step S54). For example, the processing controller 142 controls the film formation processing to be performed under the determined processing condition for the substrate processing and in the determined attitude of the stage 2. The substrate processing apparatus 100 controls the attitude of the movable part under the control of the processing controller 142 to perform the substrate processing. For example, the substrate processing apparatus 100 performs the film formation processing using the stage 2 as the attitude of the determined control parameter. Accordingly, the substrate processing apparatus 100 can perform the substrate processing that satisfies the condition to be satisfied. For example, the substrate processing apparatus 100 can perform the film formation processing in which the formed film is within the range to be satisfied. The processing condition for the performed substrate processing and the processing result of the substrate processing may be additionally learned by the model data 131.

Accordingly, by using the model data 131, the substrate processing apparatus 100 can appropriately set the value of each parameter that satisfies the condition to be satisfied by the processing result of the substrate processing, and can appropriately control the substrate processing.

As described above, the substrate processing apparatus 100 according to the embodiment includes the storage 130 and the processing controller 142. The storage 130 is implemented to store the model data 131 generated based on data (the training data 221) including, in patterns, a processing condition for substrate processing, an attitude of a movable part that affects a processing result of the substrate processing, and the processing result of the substrate processing. The processing controller 142 is configured to use the model data 131 stored in the storage 130 to control the substrate processing, including control of the processing condition for the substrate processing and control of the attitude of the movable part, according to the condition to be satisfied by the processing result of the substrate processing. Accordingly, the substrate processing apparatus 100 can appropriately control the substrate processing according to the condition to be satisfied by the processing result of the substrate processing.

In addition, the model data 131 is generated based on data (the training data 221) storing, for each pattern in which the values of at least a part of parameters, including processing parameters of the substrate processing and control parameters for controlling the attitude of the movable part, are changed, the values of the respective parameters of the pattern and the processing result of the substrate processing of the pattern. Accordingly, the substrate processing apparatus 100 can determine, by using the model data 131, the values of the plurality of parameters according to the condition to be satisfied by the processing result of the substrate processing.

The processing controller 142 uses the model data 131 to determine the values the parameters based on the condition to be satisfied by the processing result of the substrate processing, and uses the determined values of the parameters to control the substrate processing, including the control of the processing condition for the substrate processing and the attitude of the movable part. In addition, the processing controller 142 uses the model data 131 to determine values of remaining parameters based on the condition to be satisfied by the processing result of the substrate processing and the values of a part of the parameters among the plurality of parameters, and uses the values of the part of the parameters and the determined values of the remaining parameters to control the substrate processing, including the control of the processing condition for the substrate processing and the attitude of the movable part. Accordingly, the substrate processing apparatus 100 can appropriately control the substrate processing, including control of the processing condition for the substrate processing and control of the attitude of the movable part, according to the condition to be satisfied by the processing result of the substrate processing.

In addition, the model data 131 is generated based on data including the processing result of the substrate processing at predetermined measurement points on the substrate W or on the stage 2 on which the substrate W is placed. The processing controller 142 uses the model data 131 to control the processing condition for the substrate processing and the attitude of the movable part such that the processing result of the substrate processing at each of the measurement points satisfies the condition to be satisfied. Accordingly, the substrate processing apparatus 100 can appropriately control the processing condition for the substrate processing and the attitude of the movable part such that the processing result of the substrate processing at each of the measurement points satisfies the condition to be satisfied.

In addition, the movable part is the stage 2 that supports the substrate W that is a substrate processing target and having a changeable attitude. The processing controller 142 uses the model data 131 to determine the processing condition for the substrate processing and the attitude of the stage 2, according to the condition to be satisfied by the processing result of the substrate processing, and controls the substrate processing to be performed under the determined processing condition for the substrate processing and in the determined attitude of the stage 2. Accordingly, the substrate processing apparatus 100 can appropriately control the processing condition for the substrate processing and the attitude of the stage 2, according to the condition to be satisfied by the processing result of the substrate processing.

The model data 131 is generated based on data (the training data 221) through the machine learning. Accordingly, the model data 131 that can appropriately control the processing condition for the substrate processing and the attitude of the movable part can be generated, according to the condition to be satisfied by the processing result of the substrate processing.

The model data 131 is generated based on data (the training data 221) using a physical model of the substrate processing as a constraint. Accordingly, the model data 131 can be generated in accordance with the physical model of the substrate processing.

The model data generation apparatus 200 according to the embodiment includes the storage 220 and the generator 231. The storage 220 is configured to store, in patterns, data including the processing condition for the substrate processing, the attitude of the movable part that affects the processing result of the substrate processing, and the processing result of the substrate processing. The generator 231 is configured to generate, based on the data stored in the storage 220, the model data 222 for deriving the processing condition for the substrate processing and the attitude of the movable part, according to the condition to be satisfied by the processing result of the substrate processing. Accordingly, the model data generation apparatus 200 can generate the model data 222 that can appropriately control the processing condition for the substrate processing and the attitude of the movable part, according to the condition to be satisfied by the processing result of the substrate processing.

The storage 220 is configured to store, as the data in the patterns, data (the training data 221) storing, for each pattern in which the values of at least some of the plurality of parameters, including the processing parameters of the substrate processing and the control parameters for controlling the attitude of the movable part, are changed, values of the respective parameters of the pattern and the processing result of the substrate processing of the pattern. The generator 231 generates the model data 222 for deriving the values of the parameters, according to the condition to be satisfied by the processing result of the substrate processing. Accordingly, the model data generation apparatus 200 can generate the model data 222 for deriving the values of the parameters, according to the condition to be satisfied by the processing result of the substrate processing.

The storage 220 stores, as the processing result of the substrate processing, data (the training data 221) that includes the processing result of the substrate processing at predetermined measurement points on the substrate W or on the stage 2 on which the substrate W is placed. The generator 231 generates the model data 222 for deriving the processing condition for the substrate processing and the attitude of the movable part, according to the condition to be satisfied by the processing result of substrate processing at each of the measurement points. Accordingly, the model data generation apparatus 200 can generate the model data 222 that can derive the processing condition for the substrate processing and the attitude of the movable part, according to the condition to be satisfied by the processing result of the substrate processing at each of the measurement points.

The generator 231 generates, based on the data stored in the storage 220, the model data 222 through the machine learning. Accordingly, the model data generation apparatus 200 can generate the model data 222 that can appropriately control the processing condition for the substrate processing and the attitude of the movable part, according to the condition to be satisfied by the processing result of the substrate processing.

The generator 231 generates the model data 222 based on the data stored in the storage 220, using the physical model of the substrate processing as the constraint. Accordingly, the model data generation apparatus 200 can generate the model data 222 in accordance with the physical model of the substrate processing.

### [Other]

The technology disclosed in the present application is not limited to the above-described embodiment, and various modifications are possible within the scope of the gist thereof.

For example, the above-described embodiment is described by taking a case in which the attitude of the stage 2 can be changed by the driving mechanism 7 using the plurality of actuators 72 as an example. However, the present disclosure is not limited thereto. Any configuration may be used to enable the attitude of the stage 2 to be changed. For example, the substrate processing apparatus 100 may be implemented to change the attitude of the stage 2 by using a spherical bearing as disclosed in Japanese Patent Application Publication No. 2020-137294 filed by the present applicant.

In addition, in the above-described embodiment, a case in which the configuration in which one substrate W is disposed in one processing container 1 and the substrate processing (the film formation processing) is performed one by one is described as an example. However, the present disclosure is not limited thereto. The substrate processing apparatus may be implemented to perform the substrate processing on a plurality of substrates W in parallel. For example, the substrate processing apparatus 100 may have a configuration capable of performing the substrate processing (the film formation processing) on four substrates in parallel, as disclosed in Japanese Patent Application Publication No. 2020-116868 filed by the present applicant. In this case, the model data may be generated for each substrate processing performed on one substrate, and the substrate processing performed on a plurality of substrates may be controlled using the model data corresponding to the respective substrate processing. In addition, one piece of model data may be generated based on the processing condition for the respective substrate processing performed on the plurality of substrates, the attitude of the movable part, and the processing result of the substrate processing, and the substrate processing performed on the plurality of substrates may be controlled using the generated one model data. The substrate processing apparatus that performs a plurality of substrate processing in parallel may cause each substrate processing to affect each other. For example, when a part of a gas pipe that supplies a gas to the plurality of substrate processing is shared, a gas flow rate in each substrate processing affects other substrate processing. Even in such a case, by generating one piece of model data for the substrate processing on the plurality of substrates, it is possible to generate the model data in which the effect on each other are also learned.

In the above-described embodiment, a case in which the substrate processing apparatus 100 is used as a film forming apparatus and the substrate processing apparatus 100 performs the film formation processing as the substrate processing is described as an example. However, the present disclosure is not limited thereto. The substrate processing apparatus may be any apparatus that performs the substrate processing. For example, the substrate processing apparatus may be an etching apparatus, a coater apparatus, or a developer apparatus.

In addition, in the above-described embodiment, a case in which the movable part is the stage 2 and the attitude of the stage 2 is controlled using the model data 131 is described as an example. However, the present disclosure is not limited thereto. The movable part may be any part that affects the processing result of the substrate processing. For example, in the substrate processing apparatus 100, when the upper electrode such as the shower head 3 is implemented to be lifted and lowered, a height of the upper electrode affects the processing result of the substrate processing. In this case, lifting and lowering of the upper electrode may be controlled using the model data. For example, in a plasma processing apparatus such as an etching apparatus, an edge ring or other peripheral members disposed to surround a periphery of the substrate W on the stage may be implemented to be movable to control the attitude. In addition, for example, in a coater apparatus, when an arm provided with a nozzle that discharges droplets onto the substrate W is implemented to be movable, and a position and an angle of the nozzle are variable, the position and the angle of the nozzle may be controlled using the model data.

In the above-described embodiment, the processing parameters related to the film formation processing are exemplified as the processing condition for the substrate processing. Such processing parameters may be determined according to the substrate processing. For example, in an etching apparatus that performs etching processing such as plasma etching, the processing parameters related to the etching processing include, for example, a gas type of a gas to be used in the etching, a gas flow rate for each gas type, a supply time of the gas for each gas type, a pressure in the processing container 1, RF power, a processing temperature (for example, a temperature of the substrate W or a temperature of the heater 2b), an etching rate of the substrate W on the stage 2, a process log (for example, the cumulative number of processing pieces from introduction or maintenance, a cumulative processing time from introduction or maintenance), a plasma emission amount, a cross-sectional shape of the substrate W, a CD shape, a process parameter (for example, a plasma potential, a matcher position, APC accuracy, and an HV current), plasma characteristics, gas analysis (for example, Q-Mass), an impedance of the processing container 1, an RF resonance, and a plasma density.

In the above-described embodiment, a case in which the model data generation apparatus 200 generates the model data based on the training data 221 is described as an example. However, the present disclosure is not limited thereto. The storage 130 of the substrate processing apparatus 100 may store the training data 221, and the controller 140 of the substrate processing apparatus 100 may execute the functions of the generator 231 to generate the model data based on the training data 221. The model data generation apparatus 200 may generate the standard model data based on the training data 221, and the controller 140 of the substrate processing apparatus 100 may execute additional learning to generate the model data suitable for the substrate processing apparatus 100.

In the above-described embodiment, a case in which a semiconductor wafer is used as the substrate W is described as an example, and the present disclosure is not limited thereto. The substrate may be any substrate such as a glass substrate.

In the above-described embodiment, the substrate processing apparatus 100 that processes the substrate W using a capacitively coupled plasma (CCP) as an example of a plasma source is described, and the plasma source is not limited thereto. Examples of the plasma source other than the capacitively coupled plasma include an inductively coupled plasma (ICP), a microwave excited surface wave plasma (SWP), an electron cyclotron resonance plasma (ECP), and a helicon wave excited plasma (HWP).

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

With respect to the above-described embodiments, the following appendixes will be further disclosed.

### (Appendix 1)

A substrate processing apparatus includes:
a storage configured to store model data generated based on data including, in patterns, a processing condition for substrate processing, an attitude of a movable part that affects a processing result of the substrate processing, and the processing result of the substrate processing; and
a processing controller configured to use the model data stored in the storage to control the substrate processing, including control of the processing condition for the substrate processing and control of the attitude of the movable part, according to a condition to be satisfied by the processing result of the substrate processing.

### (Appendix 2)

In the substrate processing apparatus according to Appendix 1,
the model data is generated based on data including, for each pattern in which values of at least a part of parameters, including a processing parameter of the substrate processing and a control parameter for controlling the attitude of the movable part, are changed, values of respective parameters of the pattern and the processing result of the substrate processing of the pattern.

### (Appendix 3)

In the substrate processing apparatus according to Appendix 2,
the processing controller uses the model data to determine values of the parameters based on the condition to be satisfied by the processing result of the substrate processing, and uses the determined values of the parameters to control the substrate processing, including the control of the processing condition for the substrate processing and the control of the attitude of the movable part.

### (Appendix 4)

In the substrate processing apparatus according to Appendix 2 or 3,
the processing controller uses the model data to determine values of remaining parameters based on the condition to be satisfied by the processing result of the substrate processing and values of a part of the parameters among the parameters, and uses the values of the part of the parameters and the determined values of the remaining parameters to control the substrate processing, including the control of the processing condition for the substrate processing and the attitude of the movable part.

### (Appendix 5)

In the substrate processing apparatus according to any one of Appendices 1 to 4,
the model data is generated based on data including the processing result of the substrate processing at predetermined measurement points on a substrate or a stage on which the substrate is placed, and
the processing controller uses the model data to control the processing condition for the substrate processing and the attitude of the movable part such that the processing result of the substrate processing at each of the measurement points satisfies the condition to be satisfied.

### (Appendix 6)

In the substrate processing apparatus according to any one of Appendices 1 to 5,
the movable part is a stage configured to support a substrate that is a substrate processing target and having a changeable attitude, and
the processing controller uses the model data to determine the processing condition for the substrate processing and the attitude of the stage according to the condition to be satisfied by the processing result of the substrate processing, and controls the substrate processing to be performed under the determined processing condition for the substrate processing and in the determined attitude of the stage.

### (Appendix 7)

In the substrate processing apparatus according to any one of Appendices 1 to 6,
the model data is generated based on the data through machine learning.

### (Appendix 8)

In the substrate processing apparatus according to any one of Appendices 1 to 7,
the model data is generated based on the data using a physical model of the substrate processing as a constraint.

### (Appendix 9)

A model data generation apparatus includes:
a storage configured to store, in patterns, data including a processing condition for substrate processing, an attitude of a movable part that affects a processing result of the substrate processing, and the processing result of the substrate processing; and
a generator configured to generate, based on the data stored in the storage, model data for deriving the processing condition for the substrate processing and the attitude of the movable part, according to a condition to be satisfied by the processing result of the substrate processing.

### (Appendix 10)

In the model data generation apparatus according to Appendix 9,
the storage is configured to store, as the data in the patterns, data including, for each pattern in which values of at least a part of parameters, including a processing parameter of the substrate processing and a control parameter for controlling the attitude of the movable part, are changed, values of respective parameters of the pattern and the processing result of the substrate processing of the pattern, and
the generator generates the model data for deriving the values of the parameters, according to the condition to be satisfied by the processing result of the substrate processing.

### (Appendix 11)

In the model data generation apparatus according to Appendix 9 or 10,
the storage stores, as the processing result of the substrate processing, data including the processing result of the substrate processing at predetermined measurement points on a substrate or a stage on which the substrate is placed, and
the generator generates the model data for deriving the processing condition for the substrate processing and the attitude of the movable part, according to the condition to be satisfied by the processing result of the substrate processing at each of the measurement points.

### (Appendix 12)

In the model data generation apparatus according to any one of Appendices 9 to 11,
the generator generates the model data based on the data stored in the storage through machine learning.

### (Appendix 13)

In the model data generation apparatus according to any one of Appendices 9 to 11,
the generator generates the model data based on the data stored in the storage, using a physical model of the substrate processing as a constraint.

### (Appendix 14)

A substrate processing method includes:
acquiring model data generated based on data including, in patterns, a processing condition for substrate processing, an attitude of a movable part that affects a processing result of the substrate processing, and a processing result of the substrate processing; and
using the acquired model data to control the substrate processing, including control of the processing condition for the substrate processing and control of the attitude of the movable part, according to a condition to be satisfied by the processing result of the substrate processing.

### (Appendix 15)

A model data generation method includes:
storing, by a storage, and in patterns, data including a processing condition for substrate processing, an attitude of a movable part that affects a processing result of the substrate processing, and the processing result of the substrate processing; and
generating, based on the data stored in the storage, model data for deriving the processing condition for the substrate processing and the attitude of the movable part, according to a condition to be satisfied by the processing result of the substrate processing.

1. A substrate processing apparatus comprising:
a storage medium configured to store model data generated based on data including, in patterns, a processing condition for substrate processing, an attitude of a movable part that affects a processing result of the substrate processing, and the processing result of the substrate processing; and
processing circuitry configured to use the model data stored in the storage medium to control the substrate processing, including control of the processing condition for the substrate processing and control of the attitude of the movable part, according to a condition to be satisfied by the processing result of the substrate processing.

2. The substrate processing apparatus according to claim 1, wherein
the model data is generated based on data including, for each pattern in which values of at least a part of parameters, including a processing parameter of the substrate processing and a control parameter for controlling the attitude of the movable part, are changed, values of respective parameters of the pattern and the processing result of the substrate processing of the pattern.

3. The substrate processing apparatus according to claim 2, wherein
the processing circuitry uses the model data to determine values of the parameters based on the condition to be satisfied by the processing result of the substrate processing, and uses the determined values of the parameters to control the substrate processing, including the control of the processing condition for the substrate processing and the control of the attitude of the movable part.

4. The substrate processing apparatus according to claim 2, wherein
the processing circuitry uses the model data to determine values of remaining parameters based on the condition to be satisfied by the processing result of the substrate processing and values of a part of the parameters among the parameters, and uses the values of the part of the parameters and the determined values of the remaining parameters to control the substrate processing, including the control of the processing condition for the substrate processing and the attitude of the movable part.

5. The substrate processing apparatus according to claim 1, wherein
the model data is generated based on data including the processing result of the substrate processing at predetermined measurement points on a substrate or a stage on which the substrate is placed, and
the processing circuitry uses the model data to control the processing condition for the substrate processing and the attitude of the movable part such that the processing result of the substrate processing at each of the measurement points satisfies the condition to be satisfied.

6. The substrate processing apparatus according to claim 1, wherein
the movable part is a stage configured to support a substrate that is a substrate processing target and having a changeable attitude, and
the processing circuitry uses the model data to determine the processing condition for the substrate processing and the attitude of the stage according to the condition to be satisfied by the processing result of the substrate processing, and controls the substrate processing to be performed under the determined processing condition for the substrate processing and in the determined attitude of the stage.

7. The substrate processing apparatus according to claim 1, wherein
the model data is generated based on the data through machine learning.

8. The substrate processing apparatus according to claim 1, wherein
the model data is generated based on the data using a physical model of the substrate processing as a constraint.

9. A model data generation apparatus comprising:
a storage medium configured to store, in patterns, data including a processing condition for substrate processing, an attitude of a movable part that affects a processing result of the substrate processing, and the processing result of the substrate processing; and
a generator configured to generate, based on the data stored in the storage medium, model data for deriving the processing condition for the substrate processing and the attitude of the movable part, according to a condition to be satisfied by the processing result of the substrate processing.

10. The model data generation apparatus according to claim 9, wherein
the storage medium is configured to store, as the data in the patterns, data including, for each pattern in which values of at least a part of parameters, including a processing parameter of the substrate processing and a control parameter for controlling the attitude of the movable part, are changed, values of respective parameters of the pattern and the processing result of the substrate processing of the pattern, and
the generator generates the model data for deriving the values of the parameters, according to the condition to be satisfied by the processing result of the substrate processing.

11. The model data generation apparatus according to claim 9, wherein
the storage medium stores, as the processing result of the substrate processing, data including the processing result of the substrate processing at predetermined measurement points on a substrate or a stage on which the substrate is placed, and
the generator generates the model data for deriving the processing condition for the substrate processing and the attitude of the movable part, according to the condition to be satisfied by the processing result of the substrate processing at each of the measurement points.

12. The model data generation apparatus according to claim 9, wherein
the generator generates the model data based on the data stored in the storage medium through machine learning.

13. The model data generation apparatus according to claim 9, wherein
the generator generates the model data based on the data stored in the storage medium, using a physical model of the substrate processing as a constraint.

14. A substrate processing method comprising:
acquiring model data generated based on data including, in patterns, a processing condition for substrate processing, an attitude of a movable part that affects a processing result of the substrate processing, and a processing result of the substrate processing; and
using the acquired model data to control the substrate processing, including control of the processing condition for the substrate processing and control of the attitude of the movable part, according to a condition to be satisfied by the processing result of the substrate processing.

15. A model data generation method comprising:
storing, by a storage medium, and in patterns, data including a processing condition for substrate processing, an attitude of a movable part that affects a processing result of the substrate processing, and the processing result of the substrate processing; and
generating, based on the data stored in the storage medium, model data for deriving the processing condition for the substrate processing and the attitude of the movable part, according to a condition to be satisfied by the processing result of the substrate processing.

16. The substrate processing method of claim 14, further comprising:
generating the model data based on data including, for each pattern in which values of at least a part of parameters, including a processing parameter of the substrate processing and a control parameter for controlling the attitude of the movable part, are changed, values of respective parameters of the pattern and the processing result of the substrate processing of the pattern.

17. The substrate processing method of claim 16, further comprising:
using the model data to determine values of the parameters based on the condition to be satisfied by the processing result of the substrate processing, and using the determined values of the parameters to control the substrate processing, including the control of the processing condition for the substrate processing and the control of the attitude of the movable part.

18. The substrate processing method of claim 14, further comprising:
using the model data to determine values of remaining parameters based on the condition to be satisfied by the processing result of the substrate processing and values of a part of the parameters among the parameters, and using the values of the part of the parameters and the determined values of the remaining parameters to control the substrate processing, including the control of the processing condition for the substrate processing and the attitude of the movable part.

19. The substrate processing method of claim 14, further comprising:
generating the model data based on data including the processing result of the substrate processing at predetermined measurement points on a substrate or a stage on which the substrate is placed, and
using the model data to control the processing condition for the substrate processing and the attitude of the movable part such that the processing result of the substrate processing at each of the measurement points satisfies the condition to be satisfied.

20. The substrate processing method of claim 14, wherein
the movable part is a stage configured to support a substrate that is a substrate processing target and having a changeable attitude, and
the method further comprises using the model data to determine the processing condition for the substrate processing and the attitude of the stage according to the condition to be satisfied by the processing result of the substrate processing, and controlling the substrate processing to be performed under the determined processing condition for the substrate processing and in the determined attitude of the stage.
